(19) United States
(12) Patent Application Publication
(10) Pub. No.: US 2013/0078375 A1
(43) Pub. Date: Mar. 28, 2013

(54) DEPOSITION SOURCE INTEGRATION INTO COATER

(71) Applicants: Peter Krotov, San Jose, CA (US); Michael Rivkin, Los Altos, CA (US); Erel Milshtein, Cupertino, CA (US); Markus E. Beck, Scotts Valley, CA (US)

(72) Inventors: Peter Krotov, San Jose, CA (US); Michael Rivkin, Los Altos, CA (US); Erel Milshtein, Cupertino, CA (US); Markus E. Beck, Scotts Valley, CA (US)

(21) Appl. No.: 13/615,021

(22) Filed: Sep. 13, 2012

Related U.S. Application Data
(60) Provisional application No. 61/539,184, filed on Sep. 26, 2011.

(51) Int. Cl. C23C 16/44

(52) U.S. Cl. 427/248.1; 118/724

(57) ABSTRACT

An improved deposition source configuration in a process chamber can reduce the overheating in a thin film deposition system.

### CLAIM OF PRIORITY

This application claims priority under 35 U.S.C. §119(e) to U.S. Provisional Patent Application Ser. No. 61/539,184 filed on Sep. 26, 2011, which is hereby incorporated by reference in its entirety.

### TECHNICAL FIELD

This invention relates to a thin film deposition system with improved deposition source integration in a process chamber to reduce substrate overheating.

### BACKGROUND

A process chamber for depositing metals on the substrates/wafers typically can include a vapor source and a “hot box” structure built inside the chamber. The hot box walls are kept at elevated temperature to prevent condensation of the process materials on the cold chamber walls. Past deposition processes have contributed to products being of low quality, efficiency, and reliability.

### DESCRIPTION OF DRAWINGS

FIG. 1 is a cross-sectional view of a deposition chamber.

FIG. 2 is a cross-sectional view of a deposition chamber.

### DETAILED DESCRIPTION

A deposition chamber for depositing metals on the substrates/wafers can include a vapor source and a “hot box” structure built inside the chamber. The hot box walls can be kept at elevated temperature to prevent condensation of the process materials on the cold chamber walls. The configuration can also be used for transferring excessive heat generated inside the chamber to the water cooled chamber walls. However, if the components inside the chamber emit substantial amount of heat, the conventional “hot box” structure cannot assist in absorbing and transferring all the excessive energy outside the chamber.

In photovoltaic module manufacturing process, large amount of metal may need to be deposited on the substrates, which can emit substantial amount of heat. A metal deposition source can operate at high temperatures that can vary from 800 to 1700° C. The radiant heat emitted from the opening (orifice) of the source toward the substrate can be as high as 20-30 kW per linear meter of the orifice with a width of 50 mm. With an orifice width above 4-5 mm, the metal source can emit such a large amount of heat that the substrate can be overheated and the conventional “hot box” can not assist with the heat removal from the substrate. For example, in a CIGS photovoltaic module manufacturing process, metal sources with an orifice width below 4-5 mm are able to work with the conventional “hot box”. When the metal source design has several individual nozzles instead of a single rectangular nozzle, the orifice width can equal to a single rectangular opening with an area combining each of the individual nozzles. Furthermore, the surrounding shielding of the source can also radiate heat. A thin film deposition system with an improved deposition source integration in a process chamber and related methods are developed to reduce substrate overheating.

A significant portion of the emitted energy is absorbed by chamber components directly, and another portion of the emitted energy is reflected by the substrate and absorbed by chamber components. Finally, another portion of the emitted energy is absorbed by the substrate/wafer material and deposited film. This can result in overheating of certain components inside the chamber above their operating temperatures, as well as overheating of the substrates above the process recipe temperature and thus cause degrading of module performance. Similarly, for large scale semiconductor circuit, micro-electro-mechanical-system (MEMS), or nano device manufacturing process, overheating of the wafers above the recipe temperature can cause residual stress within the deposited thin film, resulting in possible device failure.

A thin film deposition system with an improved deposition source configuration in a process chamber is developed to prevent the overheating of the substrate(s)/wafer(s) by the deposition source(s) located in a close proximity above the substrate(s)/wafer(s). For example, the overheating happens because the metal deposition sources are operating at high temperature that can be in the range of about 800° C. to about 1700° C., for example. The radiant heat emitted from the opening (orifice) in the source toward the substrate can be as high as 20-30 kW per linear meter of the orifice with a width of 50 mm. A significant portion of the emitted energy is absorbed by the substrate/wafer material and deposited film. In addition to the heat directly absorbed by substrate, the hot box walls can also absorb heat, which results in heating of the hot box. With a higher temperature, the hot box can radiate the heat to the substrate creating secondary heating effect.

This can raise the substrate/wafer temperature beyond the level allowed by some process recipes, which can result in defective or degraded products. For example, thermal stress in the substrate can cause glass bending and twisting that can affect correct transportation of the substrate on the rollers. Excessive stress in the substrate can further cause its breakage.

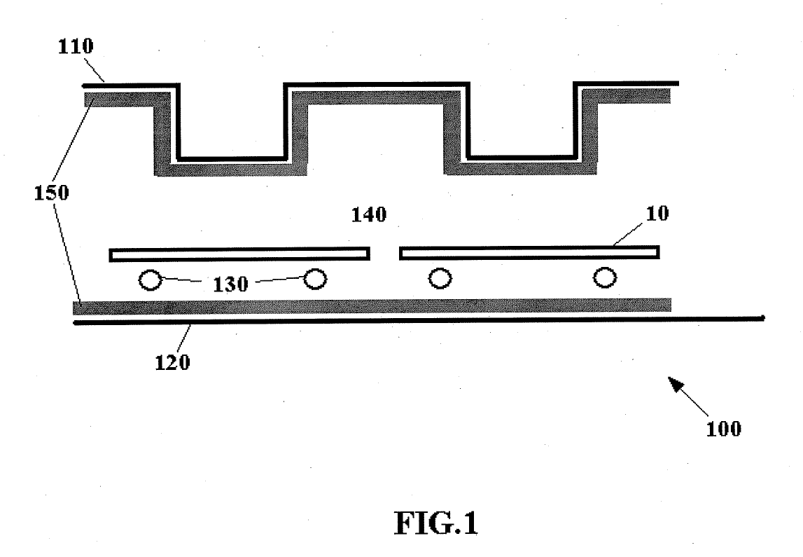

Referring to FIG. 1, deposition chamber 100 can have an enclosure including enclosure ceiling 110, enclosure floor 120, and a plurality of enclosure side walls (not shown). Substrates 10 can be transported on roller/conveyor 130 in substrate processing path 140 between enclosure ceiling 110 and enclosure floor 120. To control the temperature in the enclosure and prevent overheating of substrates 10, a heat removing structure can be included in deposition chamber 100. The heat removing structure can have thermally conductive material/layer 150 adjacent to at least one of enclosure ceiling 110, enclosure floor 120, and the enclosure side walls. The heat removing structure is capable of transferring heat and cooling the interior of the enclosure.

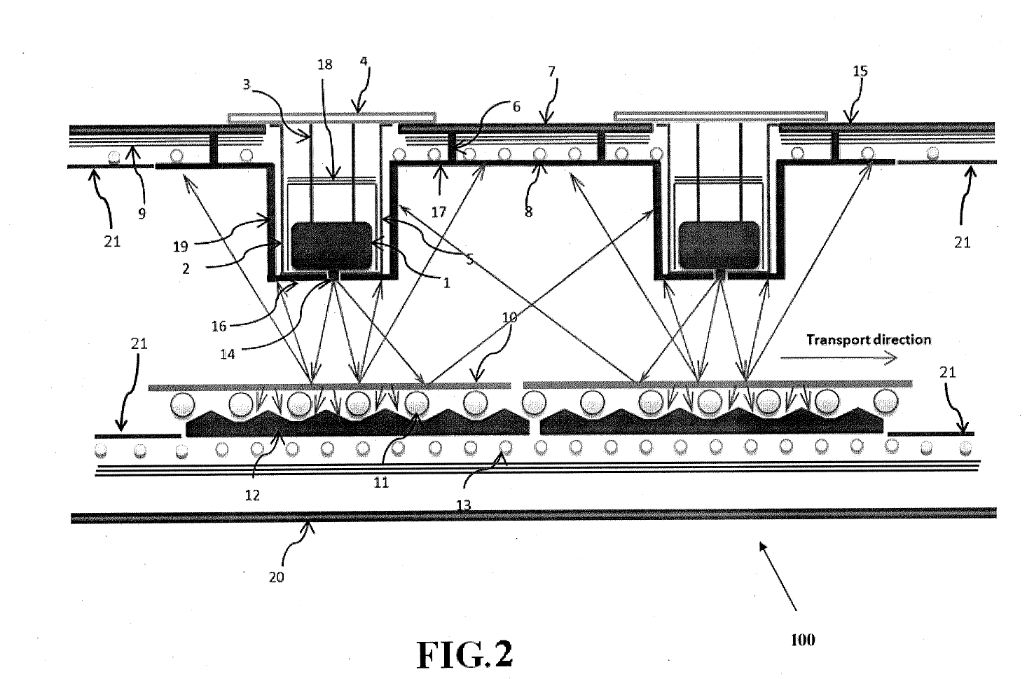

FIG. 2 is a schematic depiction of deposition chamber 100. Deposition chamber 100 can include enclosure 15. Enclosure 15 can be any suitable shape or dimension and can include any suitable material. Enclosure 15 can include enclosure ceiling 7 and enclosure floor 20. Enclosure 15 can include any suitable number of side walls. The side walls can connect enclosure ceiling 7 and enclosure floor 20 to form enclosure 15. Deposition chamber 100 can include a substrate processing path which can be defined by a plurality of rollers 11 serving as a means to convey substrate 10 through deposition chamber 100 and have material deposited on a surface of substrate 10. Any suitable transporting means can be used to transport substrate. For example, conveyor belt or chain can also be used or the substrate can be positioned on a substrate carrier.

The substrate processing path can be positioned between enclosure ceiling 7 and enclosure floor 20 such that the surface of substrate 10 onto which material will be deposited faces enclosure ceiling 7. Deposition chamber 100 can include any suitable material or combination of materials. Deposition chamber 100 can include metal. The footprint of enclosure ceiling 7 and enclosure floor 20 can be any suitable size, for example, a size sufficient to accommodate substrate 10 being conveyed along a substrate processing path including rollers 11.

Deposition chamber 100 can include vapor source 1 enclosed in vapor source enclosure 2 for emitting a vapor which can be deposited on substrate 10. Enclosed vapor source 1 can be positioned adjacent to enclosure ceiling 7. For example, enclosed vapor source 1 can be positioned beneath an opening in enclosure ceiling 7. Vapor source enclosure 2 can be connected to lid 4 covering the hole in enclosure ceiling 7. Lid 4 can provide access to the interior of enclosure 15, including access to vapor source enclosure 2. Enclosure 5 can be used to connect vapor source enclosure 2 to lid 4. FIG. 2 is a cross-section view of vapor source enclosure 2, which can be a rectangular box. Vapor source enclosure 2 can include insulations 18 and/or a temperature control component, such as heater. In some embodiments, a heater can be positioned between insulation 18 and vapor source 1.

Vapor source enclosure 2 can be of any suitable size and shape and can include any suitable material. Vapor source enclosure 2 can be designed to enclose (fully or partially) a vapor source 1. Vapor source enclosure 2 can include a solid material placed in vapor source 1. Vapor source 1 can include a metal or any other suitable material. Vapor source 1 can be connected to lid 4 with hardware 3. Any suitable hardware can be used. In this manner, lid 4 can be used to access the interior of vapor source enclosure 2 and vapor source 1. The position of vapor source 1 and vapor source enclosure 2 within enclosure 15 can be adjusted to place vapor source 1 and/or vapor source enclosure 2 in suitable position. For example, the position of vapor source 1 and/or vapor source enclosure 2 relative to the other components (e.g., enclosure ceiling 7, enclosure floor 20, and the substrate processing path) can be adjusted.

Deposition chamber 100 can include an upper heat removing structure 16. Upper heat removing structure 16 can include a bottom heat absorber surface, which can include a portion substantially parallel to the planes of enclosure ceiling 7 and/or enclosure floor 20. Upper heat removing structure 16 can include a side heat removing surface 19, which can be contiguous with a bottom heat removing surface. The heat absorber surfaces of upper heat removing structure 16 can be any suitable shape or dimension. Upper heat removing structures 16 can include a top heat removing surface 17, which can be adjacent and/or connected to enclosure ceiling 7. As shown in FIG. 2, the heat removing surfaces of upper heat removing structures 16, including a portion between vapor source 1 and substrate 10, side heat removing surface 19, and top heat removing surface 17, can substantially fully or partially enclose vapor source 1 and vapor source enclosure 2. This volume can be maintained at a temperature sufficient to maintain or generate a vapor. Deposition chamber 100 can also include a traditional hot box in addition to heat removing structure 16. Upper heat removing structure 16 can include an opening which can allow a vapor maintained or generated in vapor source 1 to be directed out of vapor source toward substrate 10.

Upper heat removing structure 16 can include a heat conductive material. The heat conductive material can be any material suitable for transferring heat. The heat conductive material can include a metal. The heat conductive material can include copper. Upper heat removing structure 16 can be positioned between vapor source enclosure 2 and a substrate 10 on the substrate processing path. In some embodiments, upper heat removing structure 16 can be positioned between vapor source 1 and vapor source enclosure 2.

The inner surface of the upper heat removing structure 16 facing substrate 10 can have an emissivity of about 0.4 to about 1.0, which can allow upper heat removing structure 16 to absorb a portion of the heat radiated and reflected by substrate 10, while minimizing its re-emission toward substrate 10. Higher emissivity is preferable to minimize re-emission of the heat back to the substrate 10. Upper heat removing structure 16 can be made of the heat conductive material, like copper. It can be thermally connected to enclosure 15 to transfer heat, for example, to enclosure ceiling 7. The heat absorbed by the upper heat removal structure 16 can be conducted through the thermally conductive connector(s) 6, which can include a standoff and can connect a portion of upper heat absorber 16 to enclosure 15.

Deposition chamber 100 can include lower heat removing structure 12 and hot box 21. Lower heat removing structure 12 can have any suitable position within enclosure 15. For example, lower heat removing structure 12 can be positioned adjacent to the substrate processing path and/or rollers 11. Lower heat removing structure 12 can be positioned beneath the substrate processing path. Lower heat removing structure 12 can be positioned beneath rollers 11 and substrates 10. Lower heat removing structure 12 can have any suitable shape or dimensions. For example, lower heat removing structure 12 may include protrusions that can interdigitate with rollers 11. Lower heat removing structure 12 can include a heat conductive material. The heat removing material can be any material suitable for transferring heat. The heat conductive material can include a metal. The heat absorption material can include copper. The inner surface of the lower heat removing structure 12 facing substrate 10 can have an emissivity of about 0.4 to about 1.0, which can allow the lower heat removing structure 12 to absorb heat radiated by substrate 10, without re-emitting it back into enclosure 15 and/or toward substrate 10. In some embodiments, heat removing structures can re-emit the heat, but smaller amount due to their lower temperature. Lower heat removing structure 12 can be connected to enclosure 15 to transfer heat, for example, to enclosure floor 20 to transfer the heat outside the process chamber.

Substrates 10 can be positioned within enclosure 15, for example, in an in-line deposition process where substrates 10 are continually conveyed into and through enclosure 15. Substrates 10 can be coated with one or more materials in deposition chamber 100. A material can be deposited onto substrate 10 by providing the material in vapor form at a high temperature and then directing the vapor at substrate 10. The vapor can condense on substrate 10 to form a layer or film of material, for example, when substrate 10 has a lower temperature than the vapor. Vapor source 1 can be heated to maintain a material in a vapor phase. Vapor source 1 can include a solid material which can be vaporized in vapor source 1. Alternatively, a vapor can be fed into vapor source 1, where it can be maintained in a vapor form. To maintain a material in vapor form or to vaporize a solid material, vapor source 1 can be heated and/or maintained at a temperature between about 500° C. and about 2000° C. Vapor source 1 can be heated and/or maintained at a temperature between about 600° C. and about 1800° C., or between about 800° C. and about 1700° C. The interior of vapor source enclosure 2 can be maintained at these, or any suitable temperatures or range of temperatures.

The vapor can be directed from vapor source 1 toward substrate 10, which can be beneath vapor source 1. The radiant heat emitted from an orifice in vapor source 1 directed toward substrate 10 (as denoted in FIG. 2 by the arrows originating from vapor source 1 toward substrate 10) can be high, for example, between about 20 kW and about 30 kW per linear meter of the vapor source orifice. The heat can be absorbed by substrate 10 or reflected or reemitted by substrate 10 back into the interior of enclosure 15 (as denoted in FIG. 2 by the arrow originating from substrate 10). This heat can be detrimental to the substrate 10 and/or products formed using substrate 10. In addition, heated substrates also emit heat that needs to be absorbed. Thus, heat from the vapor source 1 and the substrates 10 can be absorbed within enclosure 15 to protect substrates 10 from overheating. The heat can be absorbed with upper heat removing structure 16 described above. The heat can be transferred from upper heat removing structure 16 to enclosure 15, for example through thermally conductive connector 6, which can thermally connect upper heat removing structure 16 (e.g., at top heat removing surface 17) to enclosure 15 (e.g., at enclosure ceiling 7). Heat can be further absorbed by lower heat removing structure 12 described above and similarly transferred out of the process chamber.

Any suitable temperature controlling can be used to maintain components of deposition chamber 100 at suitable temperatures. For example, heat insulation 9 can be utilized at any suitable position within deposition chamber 100. Heat insulation 9 can be positioned adjacent to a wall of enclosure 15, for example, adjacent to enclosure ceiling 7. Heat insulation 9 can include any suitable thermal insulation. Heat insulation 9 can include a solid material. Heat insulation 9 can include a fibrous material. Heat insulation 9 can include a mineral. Heaters 8 can be positioned adjacent to upper heat removing structure 16 to prevent the vapor from condensing and/or being deposited on components of deposition chamber 100. Additional heaters 13 can be positioned adjacent to lower heat removing structure 12 to prevent the vapor from condensing and/or being deposited on components of deposition chamber 100. Heaters 8, 13 can include any suitable heater or combination of heaters. Heaters 8, 13 can include resistance-heated materials. Heaters 8, 13 can include ceramics.

Upper heat removing structure 16 (and/or lower heat removing structure 12) can be thermally connected to enclosure 15. Enclosure 15 can then be temperature-controlled (e.g., cooled) to help maintain upper heat removing structure 16 at a suitable temperature. Upper heat removing structure 16 (and/or lower heat removing structure 12) can be maintained at a temperature between about 200° C. and about 400° C., for example, between about 250° C. and about 300° C. Upper heat transfer structure 16 and enclosure 15 can be temperature-controlled in any suitable manner. Enclosure 15 can be thermally connected to a cooler. The cooler can include an air cooler, for example, including a cooling fin. The cooler can include any suitable cooler, such as a liquid or gas cooler using any suitable refrigerant (e.g., water). In some embodiments, upper heat removing structure 16 and/or lower heat removing structure 12 can be actively cooled by a cooler, such as a liquid or gas cooler using any suitable refrigerant (e.g., water) and/or heated with suitable heaters for controlling its temperature. In these embodiments, upper heat removing structure 16 and/or lower heat removing structure 12 may or may not be thermally connected to enclosure 15.

In some embodiments, the heat removal structure is capable of being controlled to remove sufficient heat from the enclosure to maintain a temperature profile within the enclosure or deposition chamber.

In one aspect, a deposition chamber can include an enclosure including an enclosure ceiling, an enclosure floor, and a plurality of enclosure side walls. The deposition chamber can include a substrate processing path between the enclosure ceiling and enclosure floor capable of conveying a substrate within the enclosure. The deposition chamber can include a heat removing structure including a thermally conductive material, adjacent to at least one of the enclosure ceiling, the enclosure floor, and the plurality of enclosure side walls. The heat removing structure is capable of transferring heat and cooling the interior of the enclosure.

The deposition chamber can include a vapor source in the enclosure for emitting a material vapor to be deposited on a substrate conveyed on the substrate processing path. The heat removing structure can be adjacent to the enclosure sealing. The heat removing structure can be adjacent to the enclosure floor. The heat removing structure can be adjacent to the one of the plurality of enclosure side walls. The heat removing structure can be adjacent to the vapor source and remove heat radiated from the vapor source from within the enclosure.

The thermally conductive material can include a metal. The metal can include stainless steel. The metal can include copper. The heat removal structure can be thermally connected to the enclosure. The heat removal structure can be thermally connected to a heat exchanger. The heat exchanger can include a coolant. The coolant can include gas. The coolant can include liquid. The coolant can include water.

The heat removal structure can be capable of being controlled to remove sufficient heat from the enclosure to maintain a temperature profile within the enclosure. The temperature profile can include a temperature between 100° C. and 600° C. The temperature profile can be based on the thermal tolerance of a substrate positioned on the substrate processing path.

The deposition chamber can include a heater in thermal connection with the heat removal structure capable of controlling internal temperature of the heat removal structure. The deposition chamber can include a heater proximate to the substrate processing path capable of heating a substrate positioned on the substrate processing path. The deposition chamber can include a second heat removing surface adjacent to at least one of the enclosure ceiling, the enclosure floor, and the plurality of enclosure side walls. The substrate processing path can include a plurality of rollers. The heat removing structure can have an emissivity of about 0.4 to about 1.0.

In one aspect, a method of coating a substrate can include positioning a substrate within an enclosure comprising an enclosure ceiling, an enclosure floor, and a plurality of enclosure side walls, heating a vapor source to a temperature between about 600° C. and about 1700° C. in the enclosure, to maintain a vapor, directing the vapor from the vapor source toward the substrate in the enclosure, removing heat radiating from the vapor source into the enclosure from the enclosure with a heat removing structure positioned adjacent to at least one of the enclosure ceiling, the enclosure floor, and the plurality of enclosure side walls, and transferring the heat to the enclosure.

The method can include removing heat from the vapor source with a second heat removing structure positioned adjacent to the substrate. The method can include controlling the enclosure temperature based on a temperature profile. Controlling the enclosure temperature can include maintaining an enclosure temperature of between 100° C. and 600° C.

Controlling the enclosure temperature can include heating the enclosure interior. Heating the enclosure interior can include heating the heat removal structure. Heating the enclosure interior can include heating at least one of the enclosure ceiling, the enclosure floor, and the plurality of enclosure side wall.

Controlling the enclosure temperature can include cooling the enclosure interior. Cooling the enclosure interior can include maintaining the enclosure interior at a temperature between 200° C. and 500° C. The method can include cooling the enclosure with a cooling fluid. The method can include cooling the enclosure with a cooling liquid. The method can include cooling the enclosure with a cooling gas. The method can include transferring the heat to a separate heat exchanger.

In one aspect, a method of coating a substrate can include positioning a substrate within an enclosure comprising an enclosure ceiling, an enclosure floor, and a plurality of enclosure side walls, heating a vapor source to a temperature between about 600° C. and about 1700° C. in the enclosure, to generate and maintain a vapor, directing the vapor from the vapor source toward the substrate in the enclosure, removing heat radiating from the vapor source into the enclosure from the enclosure with a heat removing structure positioned adjacent to at least one of the enclosure ceiling, the enclosure floor, and the plurality of enclosure side walls, and transferring the heat to the enclosure.

The vapor source can be positioned through an opening at the top of the enclosure. A plurality of vapor sources can be heated to a temperature to maintain the vapor, the temperature of a space between the sources being set at a controlled temperature by a plurality of heating and cooling circuits. An interface of the enclosure ceiling can support the vapor source. The enclosure ceiling interface can be wedged toward the deposition source to minimize radiation reflection towards the substrate under the source. The enclosure floor can include a debris collection surface in a shape of bended surface. The material of the vapor source enclosure and enclosure ceiling interface can be selected to minimize the heat transfer to the enclosure ceiling.

A number of embodiments of the invention have been described. Nevertheless, it will be understood that various modifications may be made without departing from the spirit and scope of the invention. It should also be understood that the appended drawings are not necessarily to scale, presenting a somewhat simplified representation of various preferred features illustrative of the basic principles of the invention.

1. A deposition chamber comprising:
an enclosure comprising an enclosure ceiling, an enclosure floor, and a plurality of enclosure side walls;
a substrate processing path between the enclosure ceiling and enclosure floor capable of conveying a substrate within the enclosure; and
a heat removing structure comprising a thermally conductive material, adjacent to at least one of the enclosure ceiling, the enclosure floor, and the plurality of enclosure side walls, wherein the heat removing structure is capable of transferring heat and cooling the interior of the enclosure.

2. The deposition chamber of claim 1, further comprising a vapor source in the enclosure for emitting a material vapor to be deposited on a substrate conveyed on the substrate processing path.

3. The deposition chamber of claim 1, wherein the heat removing structure is adjacent to the enclosure sealing.

4. The deposition chamber of claim 1, wherein the heat removing structure is adjacent to the enclosure floor.

5. The deposition chamber of claim 1, wherein the heat removing structure is adjacent to the one of the plurality of enclosure side walls.

6. The deposition chamber of claim 2, wherein the heat removing structure is adjacent to the vapor source and removes heat radiated from the vapor source from within the enclosure.

7. The deposition chamber of claim 1, wherein the thermally conductive material comprises a metal.

8. The deposition chamber of claim 7, wherein the metal comprises stainless steel.

9. The deposition chamber of claim 7, wherein the metal comprises copper.

10. The deposition chamber of claim 1, wherein the heat removing structure is thermally connected to the enclosure.

11. The deposition chamber of claim 1, wherein the heat removing structure is thermally connected to a heat exchanger.

12. The deposition chamber of claim 11, wherein the heat exchanger comprises a coolant.

13. The deposition chamber of claim 12, wherein the coolant comprises gas.

14. The deposition chamber of claim 12, wherein the coolant comprises liquid.

15. The deposition chamber of claim 15, wherein the coolant comprises water.

16. The deposition chamber of claim 1, wherein the heat removing structure is capable of being controlled to remove sufficient heat from the enclosure to maintain a temperature profile within the enclosure.

17. The deposition chamber of claim 16, wherein the temperature profile comprises a temperature between 100° C. and 600° C.

18. The deposition chamber of claim 16, wherein the temperature profile is based on the thermal tolerance of a substrate positioned on the substrate processing path.

19. The deposition chamber of claim 16, further comprising a heater in thermal connection with the heat removing structure capable of controlling internal temperature of the heat removing structure.

20. The deposition chamber of claim 1, further comprising a heater proximate to the substrate processing path capable of heating a substrate positioned on the substrate processing path.

21. The deposition chamber of claim 1, further comprising a second heat removing structure adjacent to at least one of the enclosure ceiling, the enclosure floor, and the plurality of enclosure side walls.

22. The deposition chamber of claim 1, wherein the substrate processing path comprises a plurality of rollers.

23. The deposition chamber of The deposition chamber of claim 1, wherein the heat removing structure has an emissivity of about 0.4 to about 1.0.

24. A method of coating a substrate comprising:
positioning a substrate within an enclosure comprising an enclosure ceiling, an enclosure floor, and a plurality of enclosure side walls;
heating a vapor source to a temperature between about 600° C. and about 1700° C. in the enclosure, to maintain a vapor;
directing the vapor from the vapor source toward the substrate in the enclosure;
removing heat radiating from the vapor source into the enclosure from the enclosure with a heat removing structure positioned adjacent to at least one of the enclosure ceiling, the enclosure floor, and the plurality of enclosure side walls; and
transferring the heat to the enclosure.

25. The method of claim 24, further comprising removing heat from the vapor source with a second heat removing structure positioned adjacent to the substrate.

26. The method of claim 24, further comprising controlling the enclosure temperature based on a temperature profile.

27. The method of claim 26, wherein controlling the enclosure temperature comprises maintaining an enclosure temperature of between 100° C. and 600° C.

28. The method of claim 26, wherein controlling the enclosure temperature comprises heating the enclosure interior.

29. The method of claim 28, wherein heating the enclosure interior comprises heating the heat removing structure.

30. The method of claim 28, wherein heating the enclosure interior comprises heating at least one of the enclosure ceiling, the enclosure floor, and the plurality of enclosure side wall.

31. The method of claim 26, wherein controlling the enclosure temperature comprises cooling the enclosure interior.

32. The method of claim 31, wherein cooling the enclosure interior comprises maintaining the enclosure interior at a temperature between 200° C. and 500° C.

33. The method of claim 31, further comprising cooling the enclosure with a cooling fluid.

34. The method of claim 31, further comprising cooling the enclosure with a cooling liquid.

35. The method of claim 31, further comprising cooling the enclosure with a cooling gas.

36. The method of claim 31, further comprising transferring the heat to a separate heat exchanger.

37. The method of claim 24, wherein
heating the vapor source further comprises generating the vapor.

38. The deposition chamber of claim 1, wherein the vapor source is positioned through an opening at the top of the enclosure.

39. The method of claim 24, wherein a plurality of vapor sources are heated to the temperature to maintain the vapor, and wherein the temperature of a space between the sources is set at a controlled temperature by a plurality of heating and cooling circuits.

40. The deposition chamber of claim 1, wherein an interface of the enclosure ceiling supports the vapor source.

41. The deposition chamber of claim 40, wherein the enclosure ceiling interface is wedged toward the vapor source to minimize radiation reflection towards the substrate under the source.

42. The deposition chamber of claim 1, wherein the enclosure floor comprises a debris collection surface in a shape of bended surface.

43. The deposition chamber of claim 40, wherein the material of the enclosure and the enclosure ceiling interface is selected to minimize heat transfer to the enclosure ceiling.
